(19) United States
(12) Patent Application Publication
(10) Pub. No.: US 2017/0148929 A1
(43) Pub. Date: May 25, 2017

(54) SOLAR CELL MODULE

(71) Applicant: Panasonic Intellectual Property Management Co., Ltd., Osaka (JP)

(72) Inventors: Masahiro IWATA, Osaka (JP); Haruhisa HASHIMOTO, Osaka (JP); Youhei MURAKAMI, Osaka (JP); Tasuku ISHIGURO, Osaka (JP); Hiroyuki KANNOU, Osaka (JP); Ryoji NAITO, Osaka (JP); Kazuki OHTA, Shiga (JP); Hiroshi INOUE, Osaka (JP)

(73) Assignee: Panasonic Intellectual Property Management Co., Ltd., Osaka (JP)

(21) Appl. No.: 15/423,596

(22) Filed: Feb. 3, 2017

Related U.S. Application Data
(63) Continuation of application No. PCT/JP2015/003520, filed on Jul. 13, 2015.

(30) Foreign Application Priority Data
Aug. 5, 2014 (JP) 2014-159584

(51) Int. Cl. H01L 31/02; H01L 31/05

(52) U.S. Cl. CPC H01L 31/0201; H01L 31/0504

(57) ABSTRACT

A solar cell module includes: a solar cell group including a plurality of solar cell strings arranged in a second direction, the plurality of solar cell strings each including a plurality of solar cells arranged in a first direction; a terminal box that outputs power from the solar cell group out of the solar cell module; and an interconnect tab that connects the terminal box to a first end solar cell located at an end in the first direction in one of the plurality of solar cell strings that is located at an end in the second direction, and the interconnect tab does not overlap with the first end solar cell.

### CROSS REFERENCE TO RELATED APPLICATIONS

This application is a U.S. continuation application of PCT International Patent Application Number PCT/JP2015/003520 filed on Jul. 13, 2015, claiming the benefit of priority of Japanese Patent Application Number 2014-159584 filed on Aug. 5, 2014, the entire contents of which are hereby incorporated by reference.

### BACKGROUND

1. Technical Field

One aspect of the present disclosure relates to a solar cell module.

2. Description of the Related Art

A solar cell module is usually provided with a terminal box in order to connect an interconnect tab from a solar cell and an external connection cable (for example, Japanese Unexamined Patent Application Publication No. 2011-155216). The interconnect tab from a solar cell is connected to a connection terminal provided within the terminal box. Usually, a solar cell module is produced by sandwiching solar cells sealed in an encapsulant layer between a surface-side protective member and a back-side protective member and pressing the whole.

The conventional solar cell module is problematic in that cracking or the like occurs in the solar cells by pressing or the like.

### SUMMARY

It is an object of one aspect of the present disclosure to provide a solar cell module in which the occurrence of cracking or the like in the solar cells can be suppressed.

A solar cell module according to one aspect of the present disclosure includes: a solar cell group including a plurality of solar cell strings arranged in a second direction, the plurality of solar cell strings each including a plurality of solar cells arranged in a first direction; a terminal box that outputs power from the solar cell group out of the solar cell module; and an interconnect tab that connects the terminal box to a first end solar cell located at an end in the first direction in one of the plurality of solar cell strings that is located at an end in the second direction, and the interconnect tab does not overlap with the first end solar cell.

According to the one aspect of the present disclosure, it is possible to suppress the occurrence of cracking or the like in the solar cells.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is a plan view schematically showing a solar cell module according to Embodiment 1;

FIG. 2 is a plan view schematically showing a vicinity of a first end solar cell in the solar cell module according to Embodiment 1;

FIG. 3 is a cross-sectional view taken along the line III-III shown in FIG. 2;

FIG. 4 is a plan view schematically showing a vicinity of a first end solar cell in a solar cell module according to Embodiment 2;

FIG. 5 is a plan view schematically showing a vicinity of a first end solar cell in a solar cell module according to Embodiment 3;

FIG. 6 is a plan view schematically showing a vicinity of a first end solar cell in a solar cell module according to Embodiment 4; and

FIG. 7 is a plan view schematically showing a vicinity of a first end solar cell in a solar cell module according to a comparative embodiment.

### DETAILED DESCRIPTION OF THE EMBODIMENTS

Hereinafter, embodiments of the present disclosure will be described. It is to be understood that the following embodiments are merely examples, and the one aspect of the present disclosure is not limited to the embodiments given below. Also, in the diagrams, members having substantially the same functionality may be given the same reference numerals.

In the present embodiments, x axis, y axis and z axis are three axes of a three-dimensional orthogonal coordinate system, with a z axis direction being a direction that is perpendicular to the major surface of a solar cell module, and an x axis direction and a y axis direction being two orthogonal directions that are perpendicular to the z axis.

### Embodiment 1

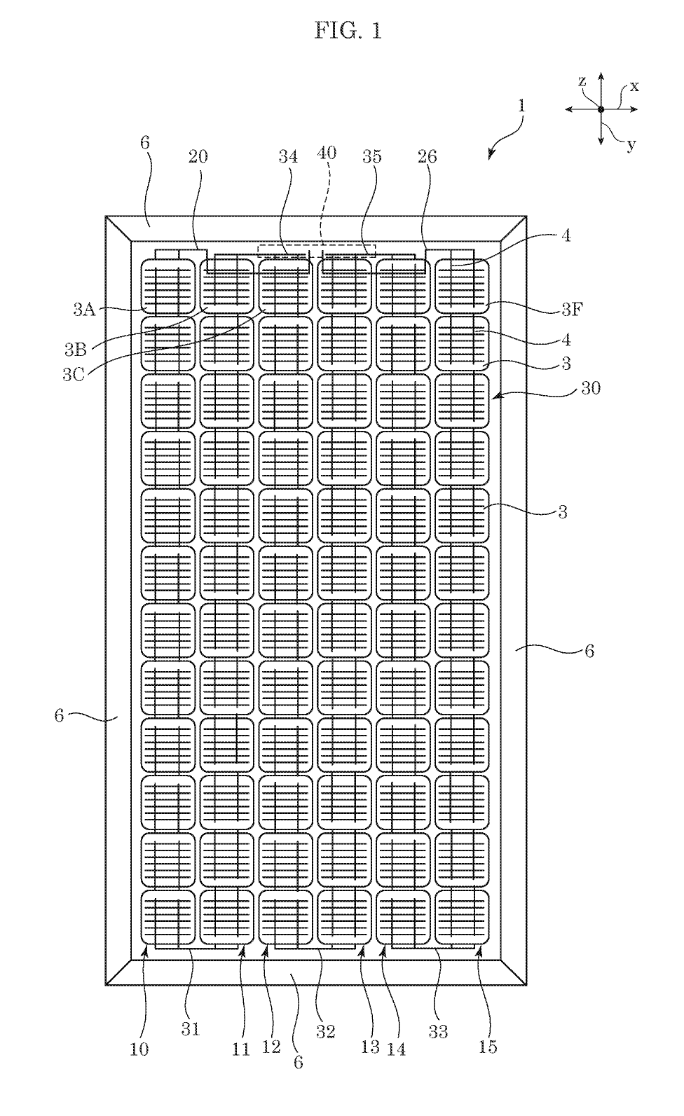

FIG. 1 is a plan view schematically showing solar cell module 1 according to Embodiment 1.

As shown in FIG. 1, solar cell module 1 includes a plurality of solar cells 3. Solar cells 3 are solar cells that include, for example, a crystalline silicon substrate such as a monocrystalline silicon substrate or a polycrystalline silicon substrate. In the present embodiment, as solar cells 3, solar cells are used in which a substantially intrinsic amorphous silicon layer is sandwiched between a monocrystalline silicon substrate and an amorphous silicon layer so as to reduce defects at an interface between the monocrystalline silicon substrate and the amorphous silicon layer and improve heterojunction interface characteristics.

The plurality of solar cells 3 arranged in a first direction (y axis direction) are electrically connected by interconnect member 4, i.e., adjacent solar cells 3 are electrically connected by interconnect member 4. The plurality of solar cells 3 that are electrically connected by interconnect member 4 constitute a solar cell string. In the present embodiment, six solar cell strings 10 to 15 are provided, and the six solar cell strings 10 to 15 are each composed of twelve solar cells 3. The plurality of solar cell strings 10 to 15 arranged in a second direction (x axis direction) constitute solar cell group 30.

Terminal box 40 is provided on one end side in the first direction (y axis direction) of solar cell group 30. Terminal box 40 is provided in order to output power from solar cell group 30 to the outside. In FIG. 1, terminal box 40 is indicated by a broken line.

Interconnect tab 20 is connected to first end solar cell 3A located at one end in the first direction (y axis direction) of solar cell string 10 located at one end in the second direction (x axis direction). Interconnect tab 20 is provided to connect first end solar cell 3A and terminal box 40. Solar cell string 10 is connected to terminal box 40 by interconnect tab 20.

Interconnect tab 26 is connected to first end solar cell 3F located at the one end in the first direction (y axis direction) of solar cell string 15 located at the other end in the second direction (x axis direction). Interconnect tab 26 is provided to connect first end solar cell 3F and terminal box 40. Solar cell string 15 is connected to terminal box 40 by interconnect tab 26.

Solar cell string 10 and solar cell string 11 are connected by extension tab 31 disposed on the other end side in the first direction (y axis direction). Solar cell string 11 and solar cell string 12 are connected by extension tab 34 disposed on the one end side in the first direction (y axis direction). Solar cell string 12 and solar cell string 13 are connected by extension tab 32 disposed on the other end side in the first direction (y axis direction). Solar cell string 13 and solar cell string 14 are connected by extension tab 35 disposed on the one end side in the first direction (y axis direction). Solar cell string 14 and solar cell string 15 are connected by extension tab 33 disposed on the other end side in the first direction (y axis direction). Also, extension tabs 34 and 35 are connected to terminal box 40.

Frame 6 is provided around solar cell group 30. In the present embodiment, solar cell module 1 is a bifacial solar cell module. Accordingly, terminal box 40 is attached to a region between frame 6 and solar cell group 30 so as to not prevent solar cell group 30 from receiving light.

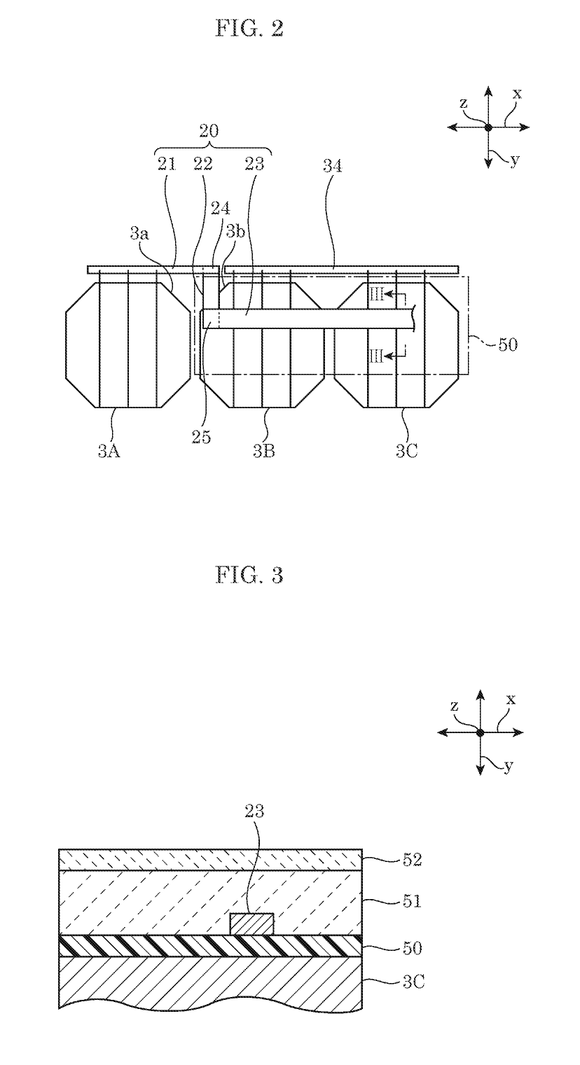

FIG. 2 is a plan view schematically showing a vicinity of first end solar cell 3A in the solar cell module according to Embodiment 1.

As shown in FIG. 2, in the present embodiment, interconnect tab 20 includes first tab 21 connected to first end solar cell 3A, third tab 23 connected to terminal box 40, and second tab 22 that connects to first tab 21 and third tab 23.

First tab 21 is formed so as to extend in the second direction (x axis direction). Second tab 22 is formed so as to extend in the first direction (y axis direction). Third tab 23 is formed so as to extend in the second direction (x axis direction).

First tab 21 and second tab 22 are connected at first connecting portion 24. First connecting portion 24 is a connecting portion of first tab 21 that connects to second tab 22. Also, first connecting portion 24 is also a connecting portion of second tab 22 that connects to first tab 21. For example, first connecting portion 24 is an overlapping portion between an end portion of first tab 21 and second tab 22.

Second tab 22 and third tab 23 are connected at second connecting portion 25. Second connecting portion 25 is a connecting portion of second tab 22 that connects to third tab 23. Also, second connecting portion 25 is also a connecting portion of third tab 23 that connects to second tab 22. For example, second connecting portion 25 is an overlapping portion between an end portion of second tab 22 and third tab 23.

In the present embodiment, first connecting portion 24 and second connecting portion 25 are soldered. To be specific, first tab 21 and second tab 22 are connected by solder at first connecting portion 24. Also, second tab 22 and third tab 23 are connected by solder at second connecting portion 25.

Second end solar cell 3B is adjacent to first end solar cell 3A in the second direction (x axis direction). As shown in FIG. 1, second end solar cell 3B is located at the one end in the first direction (y axis direction) of solar cell string 11 that is adjacent to solar cell string 10. Also, third end solar cell 3C is located at the one end in the first direction (y axis direction) of solar cell string 12 that is adjacent to solar cell string 11.

As indicated by a long dashed short dashed line in FIG. 2, insulating sheet 50 is interposed between interconnect tab 20, which is composed of first tab 21, second tab 22 and third tab 23, and second and third end solar cells 3B and 3C. In the present embodiment, insulating sheet 50 is disposed between second and third tabs 22 and 23 and second and third end solar cells 3B and 3C. Insulating sheet 50 is, for example, a resin sheet formed of a resin such as polyethylene terephthalate (PET).

FIG. 3 is a cross-sectional view taken along the line III-III shown in FIG. 2. As shown in FIG. 3, insulating sheet 50 is interposed between third end solar cell 3C and third tab 23. Back-side encapsulant layer 51 made of a resin or the like is provided between back-side protective sheet 52 and third end solar cell 3C.

In the present embodiment, as shown in FIG. 2, interconnect tab 20 is disposed so as to not overlap with first end solar cell 3A. With this configuration, it is possible to suppress the occurrence of cracking or the like in first end solar cell 3A. This effect will be described below by way of a comparative embodiment shown in FIG. 7. FIG. 7 is a plan view schematically showing a vicinity of a first end solar cell in a solar cell module according to a comparative embodiment.

As shown in FIG. 7, in the comparative embodiment, first tab 21 has a shorter length in the x axis direction, and first connecting portion 24 and second connecting portion 25 are positioned at a position closer to first end solar cell 3A than they are positioned in FIG. 2. Also, second connecting portion 25 is positioned in an overlapping position with first end solar cell 3A. Accordingly, interconnect tab 20 is disposed so as to overlap with first end solar cell 3A.

Second connecting portion 25 overlapping with first end solar cell 3A has a thickness corresponding to a total thickness of a thickness of second tab 22, a thickness of third tab 23 and a thickness of a solder portion provided between second tab 22 and third tab 23. Thus, a large stepped portion is formed between the surface of first end solar cell 3A and second connecting portion 25 in the z axis direction. For this reason, a large stress is applied to the location of first end solar cell 3A positioned below the stepped portion during a pressing step or the like when producing a solar cell module. Due to this stress, cracking or the like may occur in first end solar cell 3A.

In contrast, in Embodiment 1 shown in FIG. 2, interconnect tab 20 is disposed so as to not overlap with first end solar cell 3A. Accordingly, it is possible to suppress a situation in which a large stress is applied to first end solar cell 3A during a pressing step or the like when producing a solar cell module. For this reason, it is possible to suppress the occurrence of cracking or the like in first end solar cell 3A.

In Embodiment 1 shown in FIG. 2, second connecting portion 25 overlaps with second end solar cell 3B. However, third tab 23 extends in the x axis direction from second connecting portion 25 across the entirety of second end solar cell 3B. For this reason, the stress applied during pressing is dispersed by third tab 23. Accordingly, it is possible to suppress a situation in which a large stress is applied to the stepped portion of second connecting portion 25.

Also, in Embodiment 1 shown in FIG. 2, the length in the x axis direction of insulating sheet 50 can be shortened as compared to that in the comparative embodiment shown in FIG. 7. Accordingly, the size of insulating sheet 50 can be reduced.

Furthermore, in the present embodiment, as shown in FIG. 2, first connecting portion 24 is disposed in a region (gap) between corner portion 3a of first end solar cell 3A and corner portion 3b of second end solar cell 3B.

### Embodiment 2

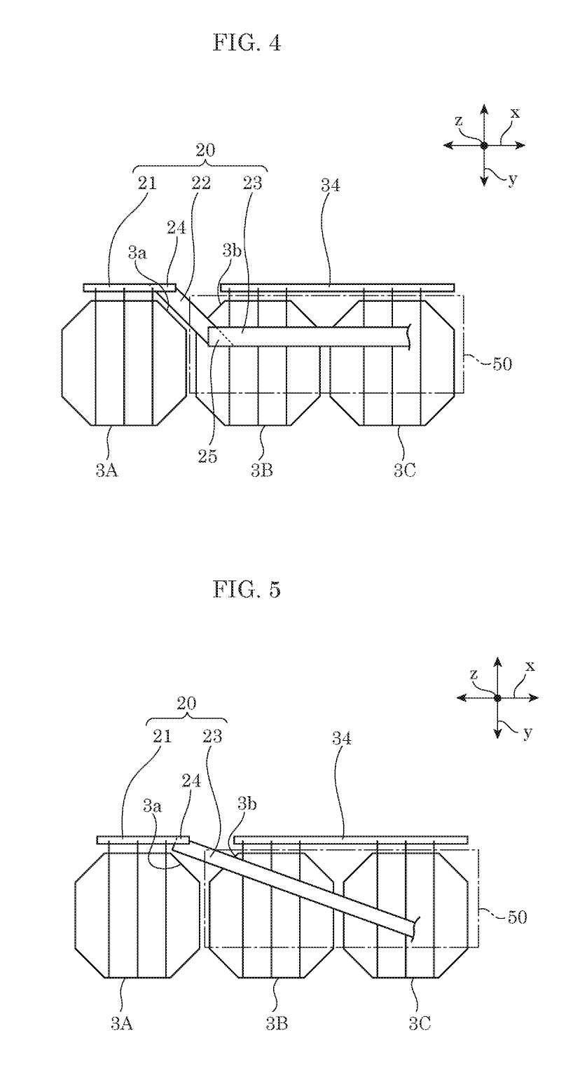

FIG. 4 is a plan view schematically showing a vicinity of first end solar cell 3A in a solar cell module according to Embodiment 2.

As shown in FIG. 4, in the present embodiment, interconnect tab 20 includes first tab 21 connected to first end solar cell 3A, third tab 23 connected to terminal box 40, and second tab 22 connecting first tab 21 and third tab 23.

In the present embodiment as well, first tab 21 is formed so as to extend in the second direction (x axis direction). On the other hand, second tab 22 is formed so as to extend obliquely from the second direction (x axis direction) toward third tab 23. Also, third tab 23 is formed so as to extend in the second direction (x axis direction). First tab 21 and second tab 22 are connected at first connecting portion 24. Second tab 22 and third tab 23 are connected at second connecting portion 25. In the present embodiment as well, first connecting portion 24 and second connecting portion 25 are soldered.

In the present embodiment as well, interconnect tab 20 is disposed so as to not overlap with first end solar cell 3A. Accordingly, it is possible to suppress a situation in which a large stress is applied to first end solar cell 3A during a pressing step or the like when producing a solar cell module. For this reason, it is possible to suppress the occurrence of cracking or the like in first end solar cell 3A.

Also, in the present embodiment as well, the length in the x axis direction of insulating sheet 50 can be shortened as compared to that in the comparative embodiment shown in FIG. 7. Accordingly, the size of insulating sheet 50 can be reduced.

In the present embodiment, second tab 22 is formed so as to extend obliquely from the second direction (x axis direction) toward third tab 23. For this reason, the total length of interconnect tab 20 can be shortened. Accordingly, a power loss due to the resistance of interconnect tab 20 can be reduced. Furthermore, by obliquely forming second tab 22, smooth insertion of insulating sheet 50 can be achieved when insulating sheet 50 is interposed between interconnect tab 20 and second and third end solar cells 3B and 3C.

In the present embodiment as well, first connecting portion 24 is disposed in a region between corner portion 3a of first end solar cell 3A and corner portion 3b of second end solar cell 3B.

### Embodiment 3

FIG. 5 is a plan view schematically showing a vicinity of first end solar cell 3A in a solar cell module according to Embodiment 3.

As shown in FIG. 5, in the present embodiment, interconnect tab 20 includes first tab 21 connected to first end solar cell 3A, and third tab 23 connected to terminal box 40.

In the present embodiment as well, first tab 21 is formed so as to extend in the second direction (x axis direction). On the other hand, third tab 23 is formed so as to obliquely extend from the second direction (x axis direction). First tab 21 and third tab 23 are connected at first connecting portion 24. Accordingly, in the present embodiment, interconnect tab 20 includes first tab 21 connected to first end solar cell 3A and third tab 23 connected to terminal box 40, and first tab 21 and third tab 23 are connected at first connecting portion 24. In the present embodiment, first connecting portion 24 is soldered.

In the present embodiment as well, interconnect tab 20 is disposed so as to not overlap with first end solar cell 3A. Accordingly, it is possible to suppress a situation in which a large stress is applied to first end solar cell 3A during a pressing step or the like when producing a solar cell module. For this reason, it is possible to suppress the occurrence of cracking or the like in first end solar cell 3A.

Also, in the present embodiment as well, the length in the x axis direction of insulating sheet 50 can be shortened as compared to that in the comparative embodiment shown in FIG. 7. Accordingly, the size of insulating sheet 50 can be reduced.

In the present embodiment, third tab 23 is formed so as to obliquely extend from the second direction (x axis direction). For this reason, the total length of interconnect tab 20 can be further shortened. Accordingly, it is possible to further reduce the power loss due to the resistance of interconnect tab 20.

In the present embodiment as well, first connecting portion 24 is disposed in a region between corner portion 3a of first end solar cell 3A and corner portion 3b of second end solar cell 3B.

### Embodiment 4

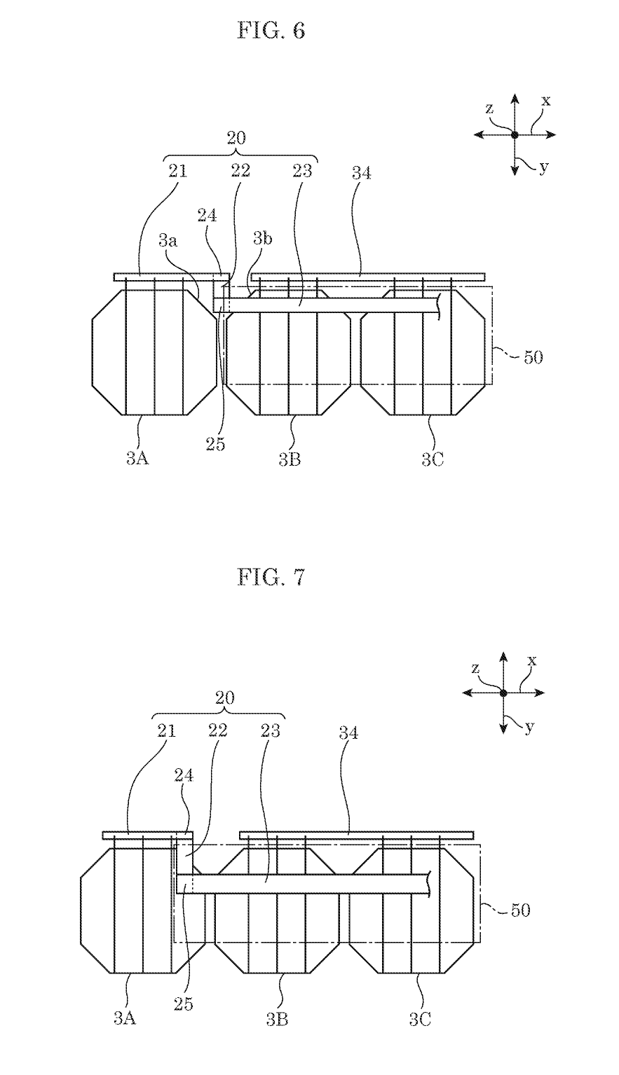

FIG. 6 is a plan view schematically showing a vicinity of first end solar cell 3A in a solar cell module according to Embodiment 4.

As shown in FIG. 6, in the present embodiment, interconnect tab 20 includes first tab 21 connected to first end solar cell 3A, third tab 23 connected to terminal box 40, and second tab 22 connecting first tab 21 and third tab 23.

In the present embodiment, first tab 21 is formed so as to extend in the second direction (x axis direction). Second tab 22 is formed so as to extend in the first direction (y axis direction). Third tab 23 is formed so as to extend in the second direction (x axis direction). First tab 21 and second tab 22 are connected at first connecting portion 24. Second tab 22 and third tab 23 are connected at second connecting portion 25. In the present embodiment, first connecting portion 24 and second connecting portion 25 are soldered.

In the present embodiment as well, interconnect tab 20 is disposed so as to not overlap with first end solar cell 3A. Accordingly, it is possible to suppress a situation in which a large stress is applied to first end solar cell 3A during a pressing step or the like when producing a solar cell module. For this reason, it is possible to suppress the occurrence of cracking or the like in first end solar cell 3A.

In the present embodiment, first connecting portion 24 and second connecting portion 25 are disposed in a region between corner portion 3a of first end solar cell 3A and corner portion 3b of second end solar cell 3B. Accordingly, second connecting portion 25 is disposed so as to not overlap with second end solar cell 3B. For this reason, in the present embodiment, it is also possible to reduce the stress applied to second end solar cell 3B.

Also, in the present embodiment as well, the length in the x axis direction of insulating sheet 50 can be shortened as compared to that in the comparative embodiment shown in FIG. 7. Accordingly, the size of insulating sheet 50 can be reduced.

In the embodiments given above, only interconnect tab 20 that is connected to first end solar cell 3A of solar cell string 10 shown in FIG. 1 is described, but interconnect tab 26 that is connected to first end solar cell 3F of solar cell string 15 shown in FIG. 1 is also configured in the same manner as interconnect tab 20 according to the embodiments given above.

In the embodiments given above, examples have been described in which interconnect tab 20 includes first tab 21, second tab 22 and third tab 23, or interconnect tab 20 includes first tab 21 and third tab 23, but the one aspect of the present disclosure is not limited thereto. Also, these tabs (first tab 21, second tab 22 and third tab 23) are not necessarily connected by solder.

In the embodiments given above, examples have been described in which solar cell module 1 is a bifacial solar cell module, but the one aspect of the present disclosure is not limited thereto.

The one aspect of the present disclosure also encompasses other embodiments obtained by making various modifications that can be conceived by a person having ordinary skill in the art to the above embodiments as well as embodiments implemented by any combination of the structural elements and the functions of the above embodiments without departing from the scope of the one aspect of the present disclosure.

While the foregoing has described one or more embodiments and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A solar cell module, comprising:
a solar cell group including a plurality of solar cell strings arranged in a second direction, the plurality of solar cell strings each including a plurality of solar cells arranged in a first direction;
a terminal box that outputs power from the solar cell group out of the solar cell module; and
an interconnect tab that connects the terminal box to a first end solar cell located at an end in the first direction in one of the plurality of solar cell strings that is located at an end in the second direction,
wherein the interconnect tab does not overlap with the first end solar cell.

2. The solar cell module according to claim 1,
wherein the interconnect tab includes a first tab connected to the first end solar cell, a third tab connected to the terminal box, and a second tab connecting the first tab and the third tab,
the first tab and the second tab are connected at a first connecting portion, and
the second tab and the third tab are connected at a second connecting portion.

3. The solar cell module according to claim 2,
wherein the first connecting portion and the second connecting portion are soldered.

4. The solar cell module according to claim 2,
wherein the first connecting portion is disposed in a region between a corner portion of the first end solar cell and a corner portion of a second end solar cell that is adjacent to the first end solar cell in the second direction.

5. The solar cell module according to claim 4,
wherein the second connecting portion is also disposed in the region.

6. The solar cell module according to claim 1,
wherein the interconnect tab includes a first tab connected to the first end solar cell and a third tab connected to the terminal box, and
the first tab and the third tab are connected at a first connecting portion.

7. The solar cell module according to claim 6,
wherein the first connecting portion is soldered.

8. The solar cell module according to claim 6,
wherein the first connecting portion is disposed in a region between a corner portion of the first end solar cell and a corner portion of a second end solar cell that is adjacent to the first end solar cell in the second direction.

9. A solar cell module, comprising:
a solar cell group including a first solar cell string and a second solar cell string arranged in a second direction, the first solar cell string and the second solar cell string each including a plurality of solar cells arranged in a first direction;
a terminal box that outputs power from the solar cell group out of the solar cell module; and
an interconnect tab that connects the terminal box to a first end solar cell located at an end in the first direction in the first solar cell string,
wherein the interconnect tab does not overlap with the first end solar cell, and overlaps with a second end solar cell located at an end in the first direction in the second solar cell string.

10. The solar cell module according to claim 9,
wherein the interconnect tab includes a first tab connected to the first end solar cell, a third tab connected to the terminal box, and a second tab connecting the first tab and the third tab,
the first tab and the second tab are connected at a first connecting portion, and
the second tab and the third tab are connected at a second connecting portion.

11. The solar cell module according to claim 10,
wherein the first connecting portion does not overlap with the first end solar cell and the second end solar cell, and
the second connecting portion overlaps with the second end solar cell.
